(19) United States
(12) Patent Application Publication
(10) Pub. No.: US 2011/0237019 A1
(43) Pub. Date: Sep. 29, 2011

(54) Method for Improving the Efficiency of Flexible Organic Solar Cells

(76) Inventors: Sheng-Fu HORNG, Hsinchu (TW); Jen-Chun Wang, Hsinchu (TW); Wei-Tse Weng, Hsinchu (TW); Tsong-Pyng Perng, Hsinchu (TW); Hsin-Fei Meng, Hsinchu (TW); Ming-Kun Lee, Hsinchu (TW)

(21) Appl. No.: 12/966,030

(22) Filed: Dec. 13, 2010

(30) Foreign Application Priority Data
Mar. 23, 2010 (TW) 099108606

(51) Int. Cl. H01L 31/0256; H01L 31/0224

(52) U.S. Cl. 438/82; 438/98; 257/E31.003; 257/E31.124

(57) ABSTRACT

The present invention discloses a method for improving the efficiency of flexible organic solar cells. The steps of the method comprise: a conductive film-coated flexible substrate is provided; and a hole blocking layer is formed on the flexible substrate by atomic layer deposition, or an active layer is formed first then a hole blocking layer is formed on the active layer by atomic layer deposition. Atomic layer deposition can control the thickness of the hole blocking layer precisely and form uniformly surface in a large area, so that the power conversion efficiency of the flexible organic solar cell is increasing effectively.

### FIELD OF THE INVENTION

The present invention relates to a method for improving the efficiency of solar cells, and more particularly to a method for improving the efficiency of flexible organic solar cells by using a hole blocking layer formed by atomic layer deposition.

### BACKGROUND OF THE INVENTION

In recent years, the increasing requirements of energy to emerging countries and fuel cost are increased so that solving energy issue becomes an important task for academia and industrial community. Solar cells are the most important topic to solve energy. The solar cells are supplied by infinite solar energy and do not need fossil fuel, and thus solar cells now are utilized in satellite, space technology, and mobile communication. In view of energy saving, demands of the effective resource use and environmental pollution preventing, solar cells increasingly become attractive energy power generators.

In 1954, the first inorganic solar cell formed on silicon (Si) is produced by Bell Laboratory in America, and such solar cell can transfer the solar radiation to electrical energy by photoelectric effect. However, the cost of the common solar cell formed on silicon wafer is higher than that of the others traditional power generation method (ex. fossil fuel thermal power plant), and doesn't meet the requirement of the production cost. Especially, the cost of solar cell formed on mono-crystalline silicon is high-priced. The cost of solar cells formed on polycrystalline silicon is lower than that of the solar cells formed on mono-crystalline silicon and the fabricating processes of the solar cells formed on mono-crystalline silicon. However, the polycrystalline silicon solar cell is still difficult to popularize in daily life. Therefore, organic conjugated polymer solar cells have several advantages, such as easily fabricating processes and easily forming large area, and gradually became research focus of solar cells in recent years.

In generally, the organic solar cells are constructed on glass substrates. However, the glass substrates have many limitations in using, such as heavy weight, easily broken, and unbendable. Thus, in order to approach a thinner size and light weight, fabricating the organic solar cells on flexible substrates is a natural trend. Moreover, the organic solar cells formed on the flexible substrates could be bonded by using roll to roll process for enhancing efficiency of production and reducing cost.

The flexible substrates typically are made of plastic materials. However, the water vapor transmission rate of the plastic substrates is higher than that of the glass substrates. Therefore, in order to enhance the stability of devices, using zinc oxide (ZnO) to form a hole blocking layer of organic solar cells is an important trend.

The traditional method of fabricating ZnO film is sol-gel process. The sol-gel process to form ZnO film needs a high-temperature sintering process over 250° C. Unfortunately, the high-temperature sintering process would spoil the flexible plastic substrate, such as deformation, and influence the following process. Obviously, the sol-gel process is improperly to apply in the flexible substrates.

Therefore, it is needed to find a method for forming ZnO film on the flexible substrates of a flexible organic solar cell without spoiling the flexible substrates, and replacing the sol-gel process which include a high-temperature sintering process.

### SUMMARY OF THE INVENTION

One object of the present invention is to provide a method of forming a hole blocking layer (ex. ZnO film) on a flexible substrate in low temperature for solving the problem of the flexible substrates are spoiled by the traditional method which includes a high-temperature sintering process.

Another object of the present invention is to provide a method which can precisely control the thin film thickness and large-area uniformity of a hole blocking layer (ex. ZnO film).

Still another object of the present invention is to provide a method of fabricating a flexible organic solar cell for effectively improving the power conversion efficiency (PCE) of the flexible organic solar cell.

In order to approach the foregoing objects, the present invention discloses a method for improving the efficiency of a flexible organic solar cell, which comprises: a conductive film-coated flexible substrate is provided; and a hole blocking layer is formed on the flexible substrate by atomic layer deposition for improving the efficiency of the flexible organic solar cell.

The atomic layer deposition has the following properties: 1. the thickness of the film can be controlled precisely; 2. a large area film growth; 3. high repeatability; 4. uniform film growth, even on a recess with high aspect ratio or a sharp surface; 5. high quality of the film grown in low temperature; and 6. multilayer materials or super lattice structures can be grown. Especially, the surface of a film is a smooth surface when the film is epitaxy or amorphous.

Therefore, using atomic layer deposition to fabricate ZnO film being a hole blocking layer of a flexible organic solar cell can precisely control the thickness of film and form a uniformly film in a large area. Moreover, the ZnO film can prevent water from entering the active layer effectively.

In view of the foregoing, the advantage of the present invention is an organic solar cell fabricated by atomic layer deposition having a longevity and high stability. Moreover, the power conversion efficiency of the solar cell is over 4%.

A detailed description is given in the following embodiments and with reference to the accompanying drawings and claims.

### BRIEF DESCRIPTION OF THE DRAWINGS

FIG. 1 shows illustration of an embodiment of a flexible solar cell according to the present invention.

FIG. 2 shows a flow chart of a fabricating method of a flexible solar cell according to the present invention.

FIGS. 3A-3E show illustrations of the fabricating method of the flexible solar cell according to the present invention.

### DETAILED DESCRIPTION OF THE PREFERRED EMBODIMENT

The invention hereinafter will be described in greater detail with preferred embodiments of the invention and accompanying illustrations. Nevertheless, it should be recognized that the preferred embodiments of the invention are not provided to limit the invention but to illustrate it. The present invention can be practiced not only in the preferred embodiments herein mentioned, but also in a wide range of other embodiments besides those explicitly described. Further, the scope of the present invention is expressly not limited to any particular embodiments except what is specified in the appended Claims.

The present invention and embodiments now are described in detail. In diagrams and descriptions as below, the same symbols are utilized to represent the same or similar elements. The main of features of the embodiments of the present invention are described in highly simplified illustration. Otherwise, the drawings of the present invention do not depict every characteristic of the actuality embodiments, and all elements of the drawings are not depicted in proportional size but in relative size.

The present invention discloses a method for improving the efficiency of a flexible organic solar cell. The main characteristic of the present invention is to use atomic layer deposition to form a hole blocking layer (HBL) of a flexible organic solar cell. Alternatively, the hole blocking layer is called an electron selective layer.

The atomic layer deposition has the following properties:
1. a precise control of the film thickness;
2. high repeatability;
3. uniform film growth, even on a recess with high aspect ratio or a sharp surface;
4. high quality of the film grown in low temperature; and
5. the growth of multilayer materials or super lattice structures.

When a film with epitaxy or amorphous is grown by atomic layer deposition, the surface of the film is a smooth surface. Thus, in the present invention, atomic layer deposition is utilized to the processes of a flexible organic solar cell for forming a hole blocking layer. By experimental verification, the efficiency of a flexible organic solar cell is improved effectively when a hole blocking layer of the flexible organic solar cell is formed by atomic layer deposition. The description in detail will be illustrated in following paragraphs.

Sequentially, the method for improving the efficiency of the flexible organic solar cell according to the present invention is introduced. At here, it's noted that the method can be utilized to any structure of flexible organic solar cells. Although the following detailed embodiment is described with a flexible inverted organic solar cell, it shouldn't be limited to this.

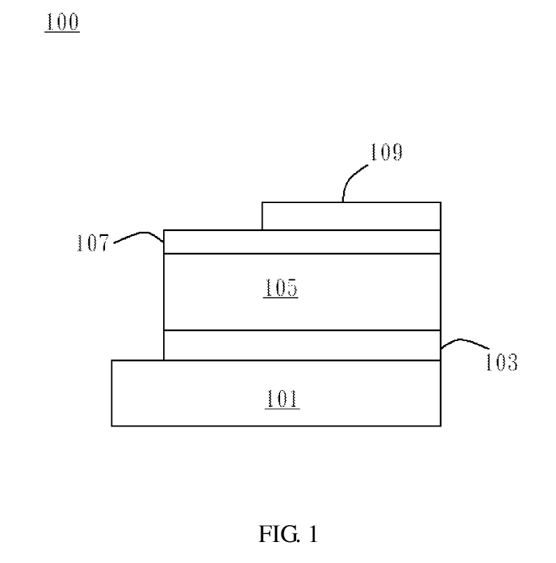

Referring to FIG. 1, it shows a cross-sectional view of an embodiment of a flexible organic solar cell according to the present invention. The flexible organic solar cell 100 comprises a flexible substrate 101 coated with a conductive film thereon, a hole blocking layer 103, an active layer 105, a hole selective layer 107, and a metal electrode 109.

In some embodiments, the flexible organic solar cell 100 comprises a flexible inverted organic solar cell, but not limited to this. In another certain embodiments, the flexible organic solar cell 100 has a structure of bulk hetero-junction (BHJ).

The conductive film-coated flexible substrate 101 comprises a flexible plastic substrate, which has flexibility and is proper to a continuous roll-and-roll process in the following processes. The conductive film comprises an indium tin oxide (ITO) film. According to the different type of the flexible organic solar cell, the ITO film could be an anode or a cathode of the flexible organic solar cell. In this embodiment, the ITO film is an anode of the flexible organic solar cell 100.

The hole blocking layer 103 is utilized to block the electric holes. In certain embodiments, the hole blocking layer 103 comprises ZnO film, titanium oxide (TiO₂) film, or cesium carbonate (Cs₂CO₃) film, but does not limit to these. The ZnO film is more stability than Cs₂CO₃ film in an environment with water and oxygen. Moreover, ZnO has higher electron mobility, and the electrons will pass through the ZnO film quickly from a PCBM ([6,6]-phenyl-C61-butyric and methyl) to an ITO film so that an electronic accumulation wouldn't be occurred in the interface between the ZnO film and the PCBM. Thus, in this embodiment, the ZnO film is used to be the hole blocking layer 103.

The active layer 105 is an absorption layer which is utilized to absorb the light of solar. In certain embodiments, the active layer 105 comprises a film made of organic materials, such as organic polymer materials, but does not limit to this. In some embodiments, the active layer 105 is a film made of conjugated polymer material. Moreover, the active layer 105 is consisted of a donor and an acceptor, which the donor is provided for electrons and the acceptor is received for electrons. In this embodiment, the material of the donor comprises poly(3-hexylthiophene-2,5-diyl) (hereafter is called P3HT) and the related derivatives thereof, and the material of the acceptor comprises 1-(3-methoxycarbonyl)propyl-1-phenyl [6,6] C61 (hereafter is called PCBM) and the derivatives of C60. The absorption wavelength of the PCBM is between 300 nm˜350 nm, and the absorption wavelength of the P3HT is between 500 nm˜600 nm. A complementary effect would be approached when above the two materials are mixed. Thus, the total absorption wavelength of the active layer 105 could be between 300 nm˜600 nm.

Furthermore, the hole selective layer 107 is also called an electron blocking layer, and to be a buffer layer of the anode. In certain embodiments, the material of the hole selective layer 107 comprises vanadium pentaoxide (V₂O₅), molybdenum trioxide (MoO₃), or poly(3,4-ethylendioxythiopene) (PEDOT) or poly(3,4-ethyl-enedioxythiophene) (PEDOT:PSS), but does not limit to these.

According to different structures of the flexible organic solar cells, the metal electrode 109 could be an anode or a cathode of the flexible organic solar cells. In this embodiment, the metal electrode 109 is the anode of the flexible organic solar cell. In some embodiments, the metal electrode 109 includes a metal with high work function. A solar cell device has a longer life time when the metal with high work function is used. Further, the metal with high work function comprises gold (Au) or silver (Ag), but does not limit to these. In another certain embodiments, the metal electrode 109 could be the cathode of the flexible organic solar cell, and the metal electrode 109 is made of a metal with low work function. The metal with low work function comprises Calcium (Ca).

Therefore, the flexible organic solar cell 100 has several advantages of using flexible substrate, such as light weight, flexibility, easy carrying, and not easy to be unbroken. Moreover, the flexible organic solar cell 100 has a longer life time of the device due to the inverted structure that the anode is made of a metal with high work function.

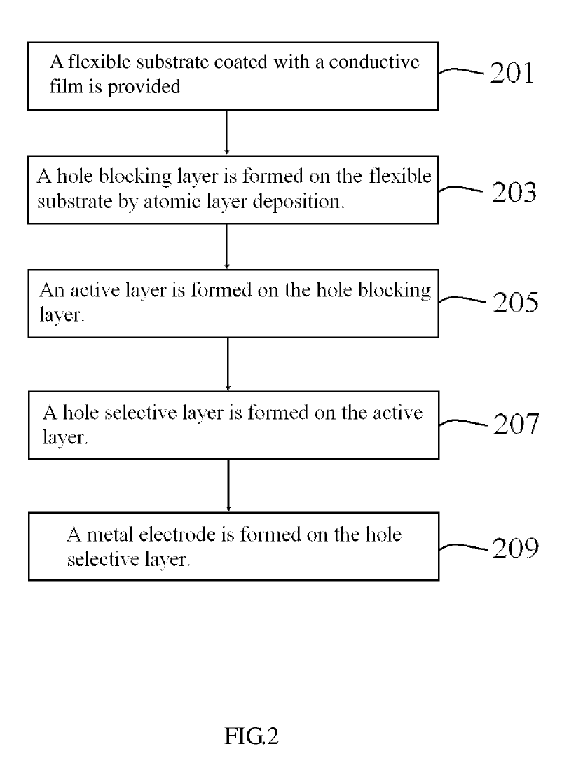

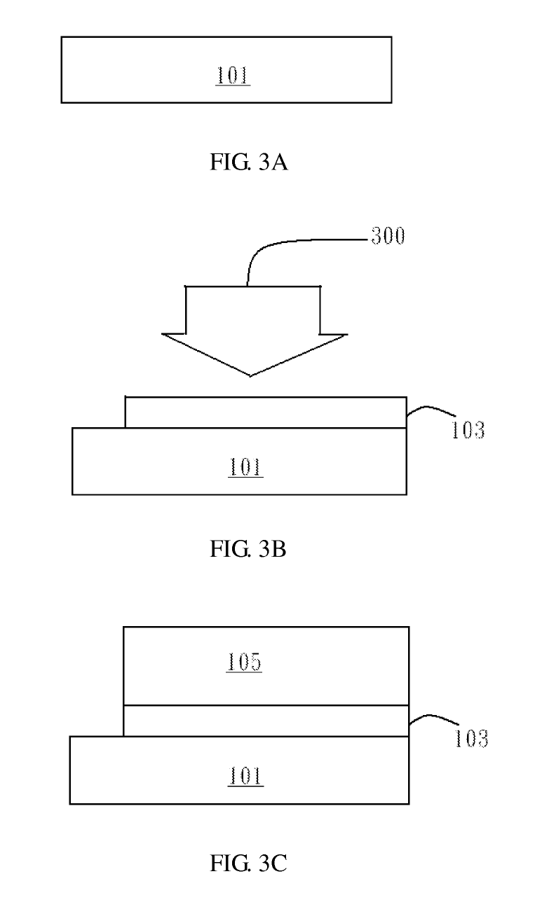

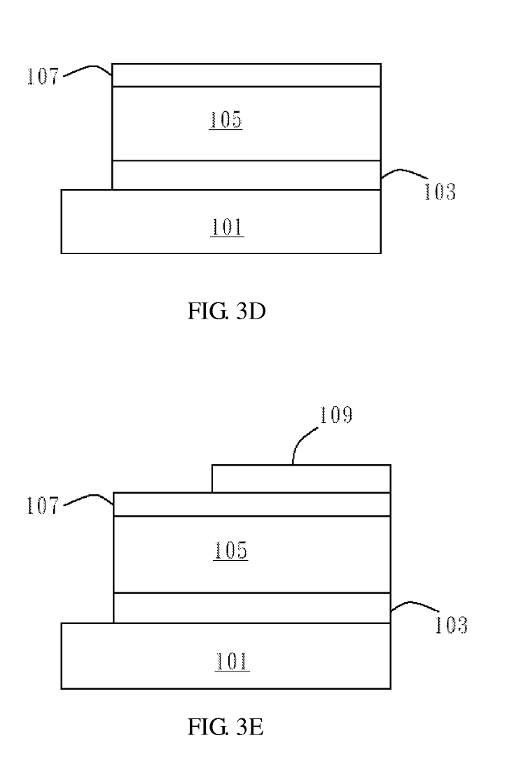

The detailed descriptions of the fabricating method of the flexible organic solar cell are illustrated, and the accompanying embodiments are utilized to describe for understanding the present invention. The detailed descriptions are accompanying with a flow chart shown in FIG. 2 and FIGS. 3A-3E to illustrate. It's noted that this embodiment is utilized a flexible inverted organic solar cell to illustrate, but the scope of the present invention is not limited to this.

First at all, referring to the step 201 shown in FIG. 2 and FIG. 3A, the step 201 shows a conductive film-coated flexible substrate is provided. In this embodiment, the flexible substrate is a plastic substrate and the conductive film is an ITO film. The ITO film is formed on the plastic substrate by RF magnetron sputtering, but does not limit to this.

In this embodiment, the ITO film is a cathode of the flexible organic solar cell. In this step, a pattern process is involved for patterning the ITO film on the flexible substrate. This pattern process is performed by a traditional process, such as photo lithography. The ITO film could be the cathode of the flexible organic solar cell after the pattern process of the ITO film. In another embodiment of the present invention, based-on different structures of the flexible organic solar cells, the conductive film is an anode of the flexible organic solar cell.

Sequentially, referring to the step 203 shown in FIG. 2 and FIG. 3B, the step 203 shows that a hole blocking layer is formed on the flexible substrate by atomic layer deposition. The hole blocking layer 103 is utilized to transfer electrons between the electrode of the flexible substrate 101 and the active layer 105. As shown in FIG. 3B, the hole blocking layer 103 is formed by atomic layer deposition 300.

Different from the normal chemical vapor deposition (CVD), the reaction process of the atomic layer deposition is utilized surface adsorption and incoming reactive gases to produce a monatomic layer so that the thickness of film is controlled precisely and a smooth surface is obtained. The growth of a binary compound is passing though a first precursor, purging gas, a second precursor, and purging gas again in turn for performing a cycle. The first and second precursors are utilized to reach the binary compound. A saturated state of the surface is approached when passing though the precursor each time so that the precursor could be covered uniformly and chemical adsorbed on the desired surface to react with surface atoms for forming a close bonding single atomic layer. Therefore, the thickness of the film would be controlled precisely and the surface of the film has large area and high smooth coating. Moreover, the thickness of the film only relates to times of the reaction cycle.

In this embodiment, the material of the hole blocking layer 103 is zinc oxide (ZnO). The ZnO film is formed by atomic layer deposition. Depending on different temperatures, the growth rate of a single cycle is between 0.18 nm to 0.21 nm. The precursor of zinc (Zn) comprises diethyl zinc (DEZn), but does not limit to this. The precursor of oxygen comprises deionized water (DI water), but does not limit to this.

Referring to the step 205 shown in FIG. 2 and FIG. 3C, the step 205 shows that an active layer is formed on the hole blocking layer. In this embodiment, the material of the active layer 105 comprises a mixed solution of P3HT and PCBM. The P3HT is utilized to be a donor and the PCBM is utilized to be an acceptor. In this case, the solvent comprises 1,2-dichlorobenzene (DCB). The mixed solution of P3HT and PCBM can be used any traditional method to form on the hole blocking layer 103. In certain embodiments of the present invention, the active layer 105 is formed by spin coating method, but does not limit to this.

Referring to the step 207 shown in FIG. 2 and FIG. 3D, the step 207 shows that a hole selective layer is formed on the active layer. The hole selective layer 107 could be formed by any traditional method. In some embodiments of the present invention, the hole selective layer 107 is formed by thermal evaporation. In others embodiment of the present invention, the material of the hole selective layer 107 comprises vanadium pentaoxide (V₂O₅), molybdenum trioxide (MoO₃), or PEDOT:PSS, but does not limit to these.

It's noted, in different structures of the flexible organic solar cells, that the step 203 and the step 207 are exchangeable steps to each other. In other words, in different structures of the flexible organic solar cells, the hole blocking layer could be formed on the active layer after the active layer has formed.

Finally, referring to the step 209 shown in FIG. 2 and FIG. 3E, the step 209 shows that a metal electrode is formed on the hole selective layer. In this embodiment, the metal electrode 109 is the anode of the flexible organic solar cell 100. Thus, the material of the metal electrode 109 could be a metal with high work function which comprises silver (Ag) or gold (Au), but does not limit to this. The fabricating method of the metal electrode 109 could be any traditional method, such as thermal evaporation deposition. It's noted that the electrode needs to connect and align the patterns of the ITO film when the metal electrode is formed.

In another embodiment of the present invention, according to the different structures of the flexible organic solar cells, the metal electrode is formed on the hole blocking layer and is the cathode of the flexible organic solar cell.

In order to show the advantages of the present invention more clearly, the experiment result of the flexible organic solar cell fabricated by utilizing atomic layer deposition according to the present invention is introduced.

The related parameters of the solar cells are introduced first. The parameters related to performance of the solar cells are mainly comprising four parameters, which are short-circuit current, open-circuit voltage, fill factor and power conversion efficiency, respectively. The short-circuit current (expressed as Isc) is a photo current measured after the solar cell illuminating. Electron-hole pairs are produced after the solar cell illuminating, and the electron-hole pairs are separated by internal electric field. Thus, the electrons and the holes are drifted and collected to cathode and anode respectively, and the photo current is measured at this time being the short-circuit current. The open-circuit voltage (expressed as Voc) is a voltage measured when the load resistance of the solar cell device is infinity. The fill factor (expressed as FF) is expressed as

$$FF = \frac{{P}_{max}}{{I}_{sx} {V}_{oc}} = \frac{{I}_{max} {V}_{max}}{{I}_{sc} {V}_{oc}}$$

when the maximum efficiency of the solar cell is expressed as Pₘₐₓ=IₘₐₓVₘₐₓ. Therefore, the efficiency of power conversion of an incident light is better when the fill factor is larger. Finally, the power conversion efficiency (PCE, expressed as η), is defined as the maximum output power of a solar cell divided by the power of an incident light, and expressed as

$$η = \frac{{P}_{max}}{{P}_{in}} = \frac{FF \times {V}_{oc} \times {I}_{sc}}{{P}_{in}} .$$

In this embodiment, the hole blocking layers of the flexible organic solar cells are fabricated at room temperature and 80° C., respectively, and the experimental results are shown in the following table 1 and table 2. The material of the hole blocking layer is zinc oxide (ZnO), and the hole blocking layer is formed by atomic layer deposition as shown above mentioned. In this embodiment, the fabricating process of ZnO is divided to five groups, no ZnO, 100 cycles, 200 cycles, 300 cycles, and 400 cycles, respectively. In atomic layer deposition, the thickness of film is controlled by times of the cycles, and the thickness of the film is higher when the deposition cycles are higher. In this embodiment, the flexible organic solar cell is a flexible inverted organic solar cell. The experimental results of the flexible inverted organic solar cells comprise the measurements of the short-circuit current, the open-circuit voltage, the fill factor and the power conversion efficiency. The no ZnO group is a contrast group.

The table 1 shows the experimental results at room temperature, and the table 2 shows the experimental results at 80° C.

TABLE 1

| | Jsc | Voc | FF | η (%) |
|---|---|---|---|---|
| No ZnO | 8.67 | 0.35 | 0.21 | 0.65 |
| 100 Cycles | 9.00 | 0.58 | 0.26 | 1.38 |
| 200 Cycles | 11.34 | 0.59 | 0.56 | 3.78 |
| 300 Cycles | 11.20 | 0.59 | 0.52 | 3.41 |
| 400 Cycles | 11.03 | 0.59 | 0.47 | 3.07 |

TABLE 2

| | Jsc | Voc | FF | η (%) |
|---|---|---|---|---|
| No ZnO | 8.67 | 0.35 | 0.21 | 0.65 |
| 100 Cycle | 9.65 | 0.59 | 0.29 | 1.61 |
| 200 Cycle | 11.90 | 0.59 | 0.60 | 4.18 |
| 300 Cycle | 11.90 | 0.58 | 0.53 | 3.69 |
| 400 Cycle | 11.80 | 0.58 | 0.48 | 3.33 |

As shown in table 1 and table 2, the power conversion efficiency (PCE) of the flexible organic solar cell that the hole blocking layer is formed by atomic layer deposition is higher than the power conversion efficiency of the flexible organic solar cell that the hole blocking layer is not made of ZnO film, obviously.

Furthermore, as shown in the table 1 and the table 2, the flexible organic solar cells which are fabricated by atomic layer deposition for forming ZnO films with 200 cycles to 400 cycles at room temperature has the power conversion efficiency approaching to about 3%-4%. The hole blocking layer of the solar cell made of ZnO with 200 cycles has the power conversion efficiency further approaching to about 4%. Moreover, the flexible organic solar cells which are fabricated by forming ZnO films with 200 cycles to 400 cycles at 80° C. has the power conversion efficiency approaching to about 3.3%˜4.2%. The hole blocking layer of the solar cell made of ZnO with 200 cycles has the power conversion efficiency further approaching to about 4.2%, which is the highest value of the power conversion efficiency of the flexible organic solar cell with a hole blocking layer made of ZnO in the current recodes.

As mentioned above, the hole blocking layer of a flexible organic solar cell is made of zinc oxide (ZnO) film by atomic layer deposition according to the present invention. The thickness of a film can be controlled precisely at low temperature, and high uniformity of the film in a large area can be produced. Furthermore, the solar cell has an ability of water-blocking. The flexible organic solar cells formed by atomic layer deposition according to the present invention can improve the longevity and stability of the device, and the power conversion efficiency of the flexible organic solar cell may be over 4%.

Forming zinc oxide (ZnO) film on a flexible substrate by atomic layer deposition according to the present invention also can be applied to a hole blocking layer with electron-hole pairs and N-type or P-type oxide semiconductor, and an intermediate layer of the a tandem solar cell.

While the embodiments of the present invention disclosed herein are presently considered to be preferred embodiments, various changes and modifications can be made without departing from the spirit and scope of the present invention. The scope of the invention is indicated in the appended claims, and all changes that come within the meaning and range of equivalents are intended to be embraced therein.

What is claimed is:

1. A method for improving the efficiency of a flexible organic solar cell, comprising:
providing a conductive film-coated flexible substrate; and
forming a hole blocking layer on said flexible substrate by atomic layer deposition for improving the efficiency of said flexible organic solar cell.

2. The method according to claim 1, wherein the material of said hole blocking layer comprises zinc oxide (ZnO).

3. The method according to claim 1, further comprising a step for forming an active layer is formed on said hole blocking layer.

4. The method according to claim 3, wherein said active layer comprises a donor and an acceptor; the material of said donor includes poly(3-hexylthiophene-2,5-diyl) and related derivatives thereof, and the material of said acceptor includes derivatives of C60.

5. The method according to claim 1, wherein said flexible organic solar cell comprises a tandem solar cell, which further comprises an intermediate layer.

6. The method according to claim 5, wherein said intermediate layer is formed by atomic layer deposition.

7. A method for improving the efficiency of a flexible organic solar cell, comprising:
providing a conductive film-coated flexible substrate;
forming a hole blocking layer on said flexible substrate by atomic layer deposition;
forming an active layer on said hole blocking layer;
forming a hole selective layer on said active layer; and
forming a metal electrode on said hole selective layer.

8. The method according to claim 7, wherein the material of said hole blocking layer comprises zinc oxide (ZnO).

9. A method for improving the efficiency of a flexible organic solar cell, comprising:
providing a conductive film-coated flexible substrate;
forming a hole selective layer on said flexible substrate;
forming an active layer on said hole selective layer;
forming a hole blocking layer on said active layer by atomic layer deposition; and
forming a metal electrode on said hole blocking layer.

10. The method according to claim 9, wherein the material of said hole blocking layer comprises zinc oxide (ZnO).
